(19) United States
(12) Patent Application Publication
(10) Pub. No.: US 2025/0349632 A1
(43) Pub. Date: Nov. 13, 2025

(54) SEMICONDUCTOR PACKAGE

(71) Applicant: Samsung Electronics Co., Ltd., Suwon-si (KR)

(72) Inventor: Jong-Won Lee, Suwon-si (KR)

(21) Appl. No.: 19/176,819

(22) Filed: Apr. 11, 2025

(30) Foreign Application Priority Data
May 10, 2024 (KR) 10-2024-0061912

(51) Int. Cl. H01L 23/055; H01L 23/00; H01L 23/373; H01L 23/498; H01L 25/07

(52) U.S. Cl. CPC H01L 23/055; H01L 23/3735; H01L 23/49816; H01L 24/16; H01L 24/32; H01L 24/73; H01L 25/072; H01L 2224/16227; H01L 2224/32225; H01L 2224/32245; H01L 2224/73204

(57) ABSTRACT

A semiconductor package is provided. The semiconductor package includes a substrate comprising an inner region extending in a first direction and a second direction that intersects the first direction, a plurality of corner regions around the inner region, first and third side faces opposite to each other in the first direction, second and fourth side faces opposite to each other in the second direction, and first and second sides that connect the first and third side faces and are opposite to each other in a third direction perpendicular to the first and second directions; a first semiconductor chip on the substrate; a metal structure on the first semiconductor chip and extending over sides of the first semiconductor chip; and a connecting structure on the second side of the substrate, and electrically connected to the first semiconductor chip, in which the metal structure inside the first to fourth side faces of the substrate, and in a region not including the plurality of corner regions among regions.

### CROSS-REFERENCE TO RELATED APPLICATION

This application claims priority from Korean Patent Application No. 10-2024-0061912, filed May 10, 2024, in the Korean Intellectual Property Office, and all the benefits accruing therefrom under 35 U.S.C. 119, the contents of which in its entirety are herein incorporated by reference.

### BACKGROUND cl 1. Field of the Invention

The present disclosure relates to a semiconductor package.

### 2. Description of the Related Art

The semiconductor package is implemented so that a semiconductor chip is provided in a suitable form for use in electronic products. Typically, in the semiconductor package, the semiconductor chip is mounted on a printed circuit board and they are electrically connected, using a bonding wire or a bump.

In recent years, a way of positioning a plurality of semiconductor chips have been proposed for a high integration and a high performance operation of the semiconductor device. For example, a multi-chip package in which the plurality of chips are mounted in a single semiconductor package, a system-in-package in which stacked heterogeneous chips operate as a single system, and the like have been proposed.

On the other hand, there is a need to properly control a warpage that occurs due to a difference in thermal expansion coefficients of the individual components that make up the semiconductor package.

### SUMMARY

Aspects of the present disclosure provide a semiconductor package having improved reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments, a semiconductor package includes a substrate comprising an inner region extending in a first direction and a second direction that intersects the first direction, a plurality of corner regions around the inner region, first and third side faces opposite to each other in the first direction, second and fourth side faces opposite to each other in the second direction, and first and second sides that connect the first and third side faces and are opposite to each other in a third direction perpendicular to the first and second directions; a first semiconductor chip which is on the substrate; a metal structure on the first semiconductor chip and extending over the sides of the first semiconductor chip; and a connecting structure which is on the second side of the substrate, and electrically connected to the first semiconductor chip, in which the metal structure is inside the first to fourth side faces of the substrate, and in a region excluding the plurality of corner regions on the first side of the substrate.

According to some embodiments, a semiconductor package includes a substrate comprising an inner region extending in a first direction and a second direction that intersects the first direction, a plurality of corner regions around the inner region, and first and second sides that are opposite to each other in a third direction perpendicular to the first direction and the second direction; a first semiconductor chip on the first side of the substrate; a metal structure which on the first side of the substrate, and on and extending over sides of the first semiconductor chip; and a connecting structure on the second side of the substrate, and electrically connected to the first semiconductor chip, wherein the metal structure is not in the plurality of corner regions and is in the inner region.

According to some embodiments, a semiconductor package includes a substrate comprising an inner region extending in a first direction and a second direction that intersects the first direction, a plurality of corner regions around the inner region, first and third side faces opposite to each other in the first direction, and second and fourth side faces opposite to each other in the second direction; a first semiconductor chip on an upper side of the substrate; a metal structure on the first semiconductor chip, and in a region that excludes the plurality of corner regions on the upper side of the substrate; an underfill material layer between the upper side of the substrate and the first semiconductor chip; a connecting bump that connects a pad of the first semiconductor chip to the substrate; and connecting structures on a lower side of the substrate, wherein the metal structure includes a plurality of first side face members adjacent the corner regions in a direction parallel to the first direction, and a plurality of second side face members adjacent the connecting structures in a direction parallel to the second direction.

Specific matters of other embodiments are included in the detailed description and drawings. dr

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an example schematic diagram showing a top view of a semiconductor package according to some embodiments of the present disclosure;

FIG. 2 is a cross-sectional view taken along line I-I′ of FIG. 1;

FIG. 3 is a diagram of the semiconductor package according to some embodiments of the present disclosure, and corresponding to FIG. 2;

FIG. 4 is an example schematic diagram of the semiconductor package according to some embodiments of the present disclosure;

FIG. 5 is a cross-sectional view taken along line II-II′ of FIG. 4;

FIG. 6 is a diagram of a semiconductor package according to some embodiments of the present disclosure, and corresponding to FIG. 5;

FIGS. 7 to 10 are example schematic diagrams of a semiconductor package according to some embodiments of the present disclosure;

FIG. 11 is an example schematic diagram of the semiconductor package according to some embodiments of the present disclosure;

FIG. 12 is a cross-sectional view taken along line III-III′ of FIG. 11;

FIG. 13 is a diagram of a semiconductor package according to some embodiments of the present disclosure, and corresponding to FIG. 12;

FIG. 14 is an example schematic diagram of a semiconductor package according to some embodiments of the present disclosure;

FIG. 15 is a cross-sectional view taken along line IV-IV′ of FIG. 14;

FIG. 16 is a diagram of a semiconductor package according to some embodiments of the present disclosure, and corresponding to FIG. 15;

FIG. 17 is a cross-sectional view of a semiconductor package according to some embodiments of the present disclosure; and

FIGS. 18 to 21 are example schematic diagrams of a semiconductor package according to some embodiments of the present disclosure.

### DETAILED DESCRIPTION OF THE EMBODIMENTS

Hereinafter, embodiments of the present disclosure will be described in detail with reference to the accompanying drawings. The same reference numerals are used for the same components in the drawings, and repeated description thereof will not be provided.

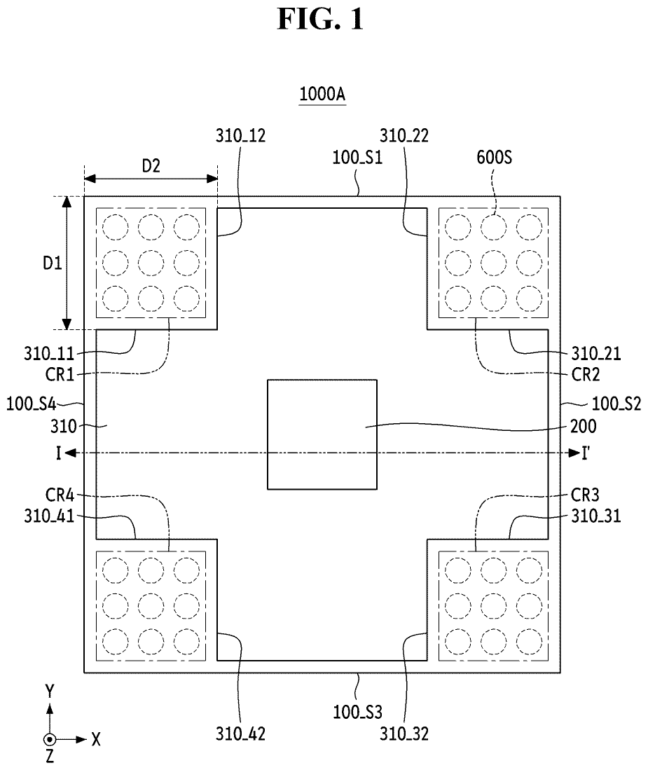

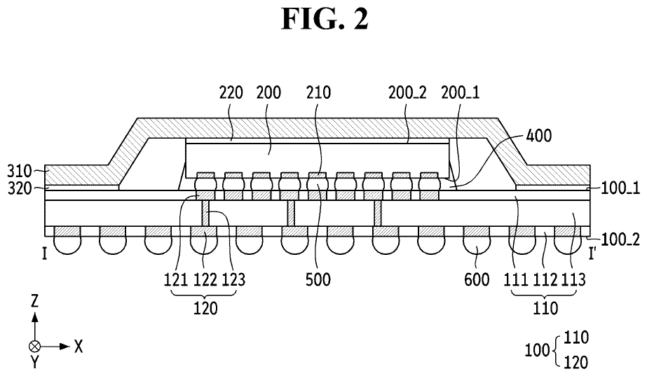

FIG. 1 is an example schematic diagram showing a top view of a semiconductor package according to some embodiments of the present disclosure. FIG. 2 is a cross-sectional view taken along line I-I′ of FIG. 1.

Referring to FIGS. 1 and 2, a semiconductor package 1000A according to some embodiments of the present disclosure may include a substrate 100, a first semiconductor chip 200, a metal structure 310, an underfill material layer 400, a connecting bump 500, and a connecting structure 600.

The substrate 100 may include an insulating layer 110 and a wiring layer 120.

The insulating layer 110 may include a first passivation film 111, a second passivation film 112, and an insulating film 113. The wiring layer 120 may include a plurality of wirings 121, 122, and 123 inside the insulating layer 110.

The substrate 100 may include a first side 100_1 and a second side 100_2 that are opposite to each other. The first side 100_1 of the substrate 100 may refer to an upper side of the substrate 100, and the second side 100_2 of the substrate 100 may refer to a lower side of the substrate 100.

The first side 100_1 of the substrate 100 may extend in a first direction Y and a second direction X that intersect each other. The first direction Y and the second direction X may refer to directions that intersect to be perpendicular to each other.

A third direction Z may refer to a direction perpendicular to each of the first direction Y and the second direction X. The first semiconductor chip 200 may be stacked on the first side 100_1 of the substrate 100 in the third direction Z. The first and second sides 100_1 and 100_2 of the substrate 100 may be opposite to each other in the third direction Z.

The substrate 100 may include an inner region extending in the first and second directions Y and X, and a plurality of corner regions CR1 to CR4 around the inner region. In some embodiments, the inner region may refer to a region on the substrate 100 that includes the metal structure 310.

The substrate 100 may include first and third side faces 100_S1 and 100_S3 opposite to each other in the first direction Y, and second and fourth side faces 100_S2 and 100_S4 opposite to each other in the second direction X. The first side 100_1 of the substrate 100 may connect the first side face 100_S1 and the third side face 100_S3, and connect the second side face 100_S2 and the fourth side face 100_S4. The second side 100_2 of the substrate 100 may connect the first side face 100_S1 and the third side face 100_S3, and connect the second side face 100_S2 and the fourth side face 100_S4.

For example, the length of each of the first to fourth side faces 100_S1, 100_S2, 100_S3, and 100_S4 in the first and second directions Y and X may be, but not limited to, 40 mm.

A plurality of external connecting structures 600 may be on the second side 100_2 of the substrate 100. The wiring layer 120 may include a plurality of wirings 121, 122, and 123 for electrically connecting the first semiconductor chip 200 and the external connecting structure 600.

The substrate 100 may include, for example, a printed circuit board (PCB) or a ceramic substrate. However, the technical idea of the present disclosure is not limited thereto.

For example, the insulating film 113 may be made up of at least one material selected from phenolic resin, epoxy resin, and polyimide. For example, the insulating film 113 may include, for example, but not limited to, at least one material selected from ABF (Ajinomoto Build-up Film), FR-4, tetrafunctional epoxy, polyphenylene ether, epoxy/polyphenylene oxide, BT (bismaleimide triazine), thermount, cyanate ester, polyimide, and liquid crystal polymer

Each of the first passivation film 111 and the second passivation film 112 may be on the insulating film 113. The first passivation film 111 and the second passivation film 112 may be solder resist. The first passivation film 111 and the second passivation film 112 may include, for example, but not limited to, a photosensitive insulating material (PID).

One face of the insulating film 113 is covered with the first passivation film 111, and a part of the first wiring 121 may be exposed without being covered with the first passivation film 111. The exposed first wiring 121 functions as a pad, and the exposed first wiring 121 and the pad 210 of the first semiconductor chip 200 may be electrically connected through a connecting bump 500.

The other face of the insulating film 113 is covered with the second passivation film 112, and a part of the second wiring 122 may be exposed without being covered with the second passivation film 112. The exposed second wiring 122 may be directly connected to the external connecting structure 600.

The wiring layer 120 may be a plurality of layers. The plurality of wirings 121, 122, and 123 may be formed as, for example, but not limited to, three layers. For example, the wiring layer 120 may include two layers or four or more layers of wiring.

Although not specifically shown, the wiring layer 120 may further include a plurality of pads and vias for electrically connecting the plurality of wirings 121, 122, and 123.

The wiring layer 120 may include, for example, a conductive material. For example, the wiring layer 120 may include at least one metal or metal alloy selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

The first semiconductor chip 200 may be on the first side 100_1 of the substrate 100. The first semiconductor chip 200 may be on the first passivation film 111. The first semiconductor chip 200 may include a first face 200_1 and a second face 200_2 that are opposite to each other. The first face 200_1 of the first semiconductor chip 200 may refer to an active face electrically connected to the substrate 100. The first face 200_1 may be a lower face of the first semiconductor chip 200, and the second face 200_2 may be an upper face of the first semiconductor chip 200.

The first semiconductor chip 200 may include an application processor (AP) chip such as a micro processor or micro controller, a CPU, a GPU, a modem, an application-specific IC (ASIC), and a logic chip such as a field programmable gate array (FPGA). Alternatively, the first semiconductor chip 200 may include a volatile memory such as a dynamic random access memory (DRAM) or a static random access memory (SRAM), and a non-volatile memory chip such as a phase-change random access memory (PRAM), a magnetoresistive random access memory (MRAM), a ferroelectric random access memory (FeRAM) or a resistive random access memory (RRAM).

The first semiconductor chip 200 may be electrically connected to the substrate 100 through the connecting bumps 500 between the first semiconductor chip 200 and the substrate 100. The first semiconductor chip 200 may be mounted on the substrate 100 by a flip chip bonding way.

The pad 210 of the first semiconductor chip 200 may be on the first face 200_1 of the first semiconductor chip 200. The pad 210 may include, for example, but not limited to, copper (Cu), copper alloy, nickel (Ni), palladium (Pd), platinum (Pt), gold (Au), cobalt (Co), and combinations thereof.

A heat transfer material layer 220 may be between the second face 200_2 of the first semiconductor chip 200 and the metal structure 310. The heat transfer material layer 220 may be above the first semiconductor chip 200.

For example, the heat transfer material layer 220 may include, but not limited to, a thermally conductive and electrically insulating material. The heat transfer material layer 220 may serve to insulate the first semiconductor chip 200 and the metal structure 300. The heat dissipation characteristics of the first semiconductor chip 200 may be improved through the heat transfer material layer 220.

The metal structure 310 may be around the first semiconductor chip 200. From a top planar viewpoint, the metal structure 310 may surround or be over the second face 200_1 and the side face of the first semiconductor chip 200. The metal structure 310 may be on the first semiconductor chip 200 and extend over the side face of the first semiconductor chip 200. The metal structure 310 may be on the second face 200_1 of the first semiconductor chip 200. The metal structure 310 may be on the side face of the first semiconductor chip 200.

In each of the plurality of corner regions CR1 to CR4, the metal structure 310 may be inside the first to fourth side faces 100_S1 to 100_S4 of the substrate 100.

The metal structure 310 may not be in each of the plurality of corner regions CR1 to CR4. From the top planar viewpoint, in each of the plurality of corner regions CR1 to CR4, the metal structure 310 may expose or not be on the first side 100_1 of the substrate 100.

The metal structure 310 may be on the first side 100_1 of the substrate 100. As illustrated, the metal structure 310 is in a region excluding the plurality of corner regions CR1 to CR4, that is, in an inner region that does not include the plurality of corner regions CR1 to CR 4.

From the top planar viewpoint, the side faces 310_11, 310_12, 310_21, 310_22, 310_31, 310_32, 310_41 and 310_42 of the metal structure 310 may have a shape recessed toward the inside of the substrate 100.

The metal structure 310 may include, in the first corner region CR1, a first side face first member 310_11 spaced apart from the first side face 100_S1 of the substrate 100 in a direction parallel to the first direction Y, and a first side face second member 310_12 spaced apart from the fourth side face 100_S4 of the substrate 100 in a direction parallel to the second direction X.

The metal structure 310 may include, in the second corner region CR2, a second side face first member 310_21 spaced apart from the first side face 100_S1 of the substrate 100 in the direction parallel to the first direction Y, and a second side face second member 310_22 spaced apart from the second side face 100_S2 of the substrate 100 in the direction parallel to the second direction X.

The metal structure 310 may include, in the third corner region CR3, a third side face first member 310_31 spaced apart from the third side face 100_S3 of the substrate 100 in the direction parallel to the first direction Y, and a third side face second member 310_32 spaced apart from the second side face 100_S2 of the substrate 100 in the direction parallel to the second direction X.

The metal structure 310 may include, in the fourth corner region CR4, a fourth side face first member 310_41 spaced apart from the third side face 100_S3 of the substrate 100 in the direction parallel to the first direction Y, and a fourth side face second member 310_42 spaced apart from the fourth side face 100_S4 of the substrate 100 in the direction parallel to the second direction X.

The metal structure 310 may be spaced apart from each of the first and third side faces 100_S1 and 100_S3 of the substrate 100 by a first distance D1 in the direction parallel to the first direction Y.

The metal structure 310 may be spaced apart from each of the second and fourth side faces 100_S2 and 100_S4 of the substrate 100 by a second distance D2 in the direction parallel to the second direction X.

Specifically, the first side face first member 310_11 may be spaced apart from the first side face 100_S1 of the substrate 100 by the first distance D1 in the direction parallel to the first direction Y. The first side face second member 310_12 may be spaced apart from the fourth side face 100_S4 of the substrate 100 by the second distance D2 in the direction parallel to the second direction X.

The second side face first member 310_21 may be spaced apart from the first side face 100_S1 of the substrate 100 by the first distance D1 in the direction parallel to the first direction Y. The second side face second member 310_22 may be spaced apart from the second side face 100_S2 of the substrate 100 by the second distance D2 in the direction parallel to the second direction X.

The third side face first member 310_31 may be spaced apart from the third side face 100_S3 of the substrate 100 by the first distance D1 in the direction parallel to the first direction Y. The third side face second member 310_32 may be spaced apart from the second side face 100_S2 of the substrate 100 by the second distance D2 in the direction parallel to the second direction X.

The fourth side face first member 310_41 may be spaced apart from the third side face 100_S3 of the substrate 100 by the first distance D1 in the direction parallel to the first direction Y. The fourth side face second member 310_42 may be spaced apart from the fourth side face 100_S4 of the substrate 100 by the second distance D2 in the direction parallel to the second direction X.

In this case, for example, each of the first distance D1 and the second distance D2 may be, but not limited to, 2 mm to 3 mm.

Referring to FIG. 1, the metal structure 310 may be, but not limited to, a cross (+) shape from the top planar viewpoint. In some other embodiments, the metal structure 310 may be formed in various shapes from the top planar viewpoint.

For example, the metal structure 310 may include at least one metal or metal alloy selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C). When the metal structure 310 is a heat slug, the metal structure 310 may include at least one of copper (Cu) and nickel (Ni).

The frame 320 may attach the metal structure 310 onto the first side 100_1 of the substrate 100. The frame 320 may be between the metal structure 310 and the first side 100_1 of the substrate 100.

The underfill material layer 400 may be formed on the substrate 100. The underfill material layer 400 may be between the first side 100_1 of the substrate 100 and the first semiconductor chip 200.

The underfill material layer 400 may prevent breakage or the like of the first semiconductor chip 200 by fixing the first semiconductor chip 200 onto the substrate 100. The underfill material layer 400 may cover the side part of the connecting bumps 500. The connecting bumps 500 may extend into the underfill material layer 400 to electrically connect the substrate 100 and the first semiconductor chip 200.

The underfill material layer 400 may include, but not limited to, an insulating polymer material such as EMC (epoxy molding compound). For example, the underfill material layer 400 may include an insulating material with excellent fluidity. As a result, the underfill material layer 400 may efficiently fill a narrow space between the substrate 100 and the first semiconductor chip 200. Meanwhile, since the underfill material layer 400 is formed on the substrate 100 with a fluidity material as described above, the shape of the underfill material layer 400 is not limited to the shape shown in this drawing.

The connecting bump 500 may connect the pad 210 of the first semiconductor chip 200 and the substrate 100. For example, the connecting bump 500 may be connected to at least a part of the first wiring 121 of the substrate 100.

The connecting bump 500 may have, for example, but not limited to, a spherical shape or an elliptical spherical shape. The connecting bump 500 may include, for example, but not limited to, tin (Sn), indium (In), bismuth (Bi), antimony (Sb), copper (Cu), silver (Ag), zinc (Zn), lead (Pb) or a combination thereof.

The external connecting structure 600 may be on the lower side 100_2 of the substrate 100. The external connecting structure 600 may be electrically connected to the first semiconductor chip 200 through the wiring layer 120.

The external connecting structure 600 may include an outermost connecting structure 600S that is closest to the first to fourth side faces 100_S1, 100_S2, 100_S3, and 100_S4 of the substrate 100 along the first and second directions Y and X.

From the top planar viewpoint, the plurality of first side face members 310_11, 310_21, 310_31, and 310_41 of the metal structure 310 may be inside the outermost connecting structure 600S in the direction parallel to the first direction Y. From the top planar viewpoint, the plurality of second side face members 310_12, 310_22, 310_32, and 310_42 of the metal structure 310 may be inside the outermost connecting structure 600S in the direction parallel to the second direction X. The plurality of first side face members 310_11, 310_21, 310_31, and 310_41 are adjacent the corner regions CR1 to CR4 in a direction parallel to the first direction Y, and a plurality of second side face members 310_12, 310_22, 310_32, and 310_42 are adjacent the corner regions CR1 to CR4 in a direction parallel to the second direction X.

The number of external connecting structures 600 in the plurality of corner regions CR1 to CR4 may be two or more in each of the first direction Y and the second direction X. For example, referring to FIG. 1, although the number of external connecting structures 600 in the corner regions CR1 to CR4 is shown to be three in each of the first direction Y and the second direction X, the number thereof is not limited thereto.

The external connecting structure 600 may have, for example, but not limited to, a spherical shape or an elliptical spherical shape. The external connecting structure 600 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof, but the technical idea of the present disclosure is not limited thereto.

The external connecting structure 600 may electrically connect the substrate 100 to an external device. Therefore, the external connecting structure 600 may provide an electrical signal to the substrate 100 or provide the electrical signal provided from the substrate 100 to an external device.

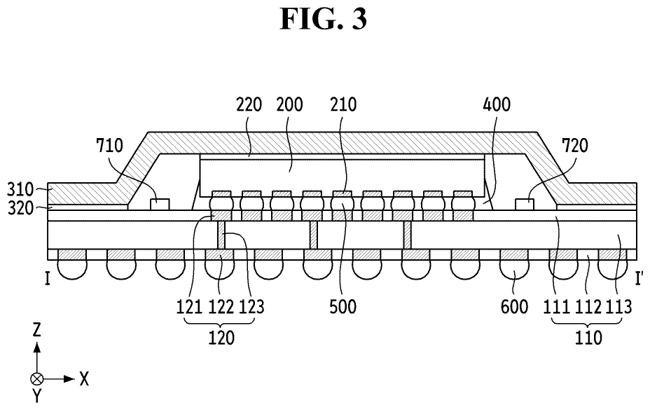

FIG. 3 is a diagram of a semiconductor package according to some embodiments of the present disclosure, and which corresponds to FIG. 2. For convenience of explanation, differences from the semiconductor package described using FIGS. 1 and 2 will be mainly explained.

Referring to FIG. 3, the semiconductor package according to some embodiments may further include passive elements 710 and 720.

The passive elements 710 and 720 may be on the first side 100_1 of the substrate 100 to be spaced apart from the first semiconductor chip 200. The metal structure 310 may surround or be over the passive elements 710 and 720 from the top planar viewpoint.

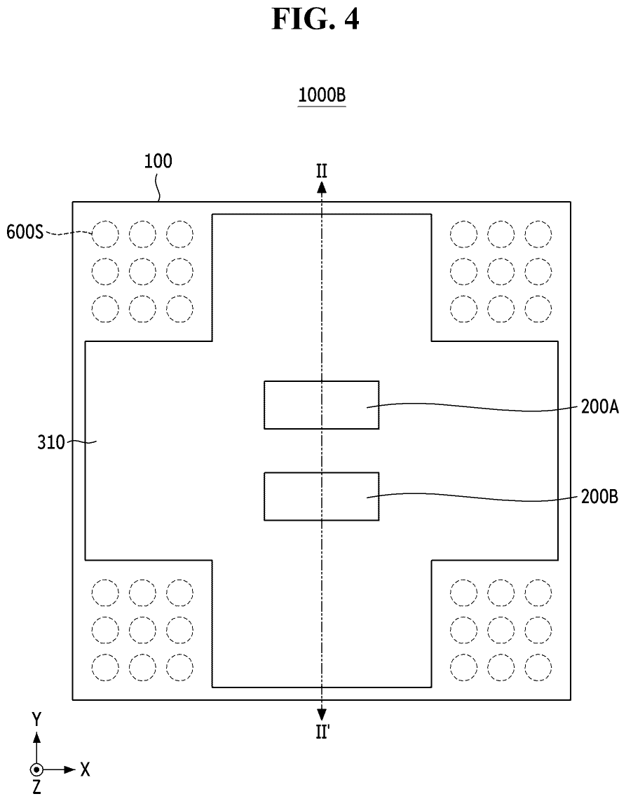

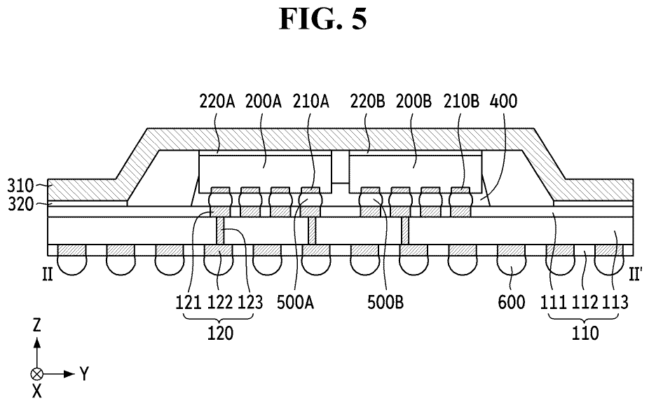

FIG. 4 is an example schematic diagram of a semiconductor package according to some embodiments of the present disclosure. FIG. 5 is a cross-sectional view taken along line II-II′ of FIG. 4. For convenience of explanation, differences from the semiconductor package explained using FIGS. 1 to 3 will be mainly explained.

Referring to FIG. 4 and FIG. 5, a semiconductor package 1000B according to some embodiments may include first and second semiconductor chips 200A and 200B. The first and second semiconductor chips 200A and 200B may be spaced apart from each other in the first direction Y. The semiconductor package 1000B according to some embodiments may include a plurality of semiconductor chips. The number of semiconductor chips is not limited to those shown in the drawings.

The first semiconductor chip 200A may be on the first side 100_1 of the substrate 100. The first semiconductor chip 200A may be on the first passivation film 111.

The first semiconductor chip 200A may include an application processor (AP) chip such as a micro processor or a micro controller, a CPU, a GPU, a modem, an application-specific IC (ASIC), and a logic chip such as a field programmable gate array (FPGA).

The first semiconductor chip 200A may be electrically connected to the substrate 100 through a first connecting bump 500A between the first semiconductor chip 200A and the substrate 100. The first semiconductor chip 200A may be mounted on the substrate 100 by a flip chip bonding way.

The first connecting bump 500A may connect a pad 210A of the first semiconductor chip 200A to the substrate 100. For example, the first connecting bump 500A may be connected to a part of the first wiring 121 of the substrate 100.

The first connecting bump 500A may have, for example, but not limited to, a spherical shape or an elliptical spherical shape. The first connecting bump 500A may include, for example, but not limited to, tin (Sn), indium (In), bismuth (Bi), antimony (Sb), copper (Cu), silver (Ag), zinc (Zn), lead (Pb), and combinations thereof.

The pad 210A of the first semiconductor chip 200A may be on the active face of the first semiconductor chip 200A. The pad 210A may include, for example, but not limited to, for example, copper (Cu), copper alloy, nickel (Ni), palladium (Pd), platinum (Pt), gold (Au), cobalt (Co), and combinations thereof.

The first heat transfer material layer 220A may be between the upper face of the first semiconductor chip 200A and the metal structure 310. The first heat transfer material layer 220A may be on the first semiconductor chip 200A.

For example, the first heat transfer material layer 220A may include, but not limited to, a thermally conductive and electrically insulating material.

The second semiconductor chip 200B may be on the first side 100_1 of the substrate 100. The second semiconductor chip 200B may be on the first passivation film 111.

The second semiconductor chip 200B may include an application processor (AP) chip such as a micro processor or micro controller, a CPU, a GPU, a modem, an application-specific IC (ASIC), and a logic chip such as a field programmable gate array (FPGA).

The second semiconductor chip 200B may be electrically connected to the substrate 100 through a second connecting bump 500B between the second semiconductor chip 200B and the substrate 100. The second semiconductor chip 200B may be mounted on the substrate 100 by the flip chip bonding way.

The second connecting bump 500B may connect the pad 210B of the second semiconductor chip 200B to the substrate 100. For example, the second connecting bump 500B may be connected to a part of the first wiring 121 of the substrate 100.

The second connecting bump 500B may have, for example, but not limited to, a spherical shape or an elliptical spherical shape. The second connecting bump 500B may include, for example, but not limited to, tin (Sn), indium (In), bismuth (Bi), antimony (Sb), copper (Cu), silver (Ag), zinc (Zn), lead (Pb), and combinations thereof.

The pad 210B of the second semiconductor chip 200B may be on the active face of the second semiconductor chip 200B. The pad 210B may include, for example, but not limited to, copper (Cu), copper alloy, nickel (Ni), palladium (Pd), platinum (Pt), gold (Au), cobalt (Co), and combinations thereof.

The second heat transfer material layer 220B may be between the upper face of the second semiconductor chip 200B and the metal structure 310. The second heat transfer material layer 220B may be on the second semiconductor chip 200B.

For example, the second heat transfer material layer 220B may include, but not limited to, a thermally conductive and electrically insulating material.

The underfill material layer 400 may be formed on the substrate 100. The underfill material layer 400 may be between the first side 100_1 of the substrate 100 and the first and second semiconductor chips 200A and 200B. The underfill material layer 400 may wrap each of the side parts of the first connecting bump 500A and the second connecting bump 500B. The underfill material layer 400 may include, but not limited to, an insulating polymer material such as epoxy molding compound (EMC).

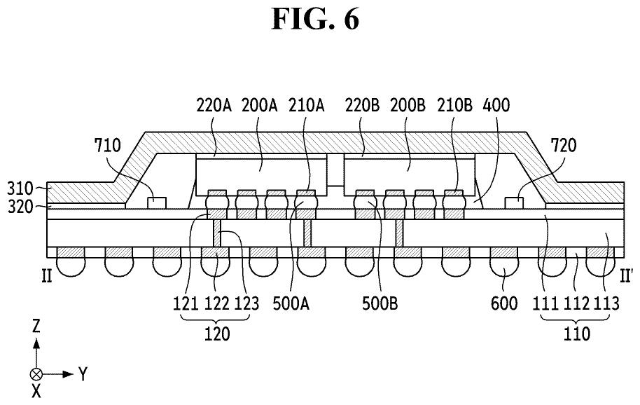

FIG. 6 is a diagram of a semiconductor package according to some embodiments of the present disclosure, and which corresponds to FIG. 5. For convenience of explanation, differences from the semiconductor package explained using FIG. 5 will be mainly explained.

Referring to FIG. 6, the semiconductor package according to some embodiments may further include passive elements 710 and 720.

The passive elements 710 and 720 may be on the first side 100_1 of the substrate 100 to be spaced apart from the first and second semiconductor chips 200A and 200B. The metal structure 310 may surround or be over the passive elements 710 and 720 from the top planar viewpoint. On the basis of the first direction Y, the passive elements 710 and 720 may be between the metal structure 310 and the first semiconductor chip 200A, and between the metal structure 310 and the second semiconductor chip 200B.

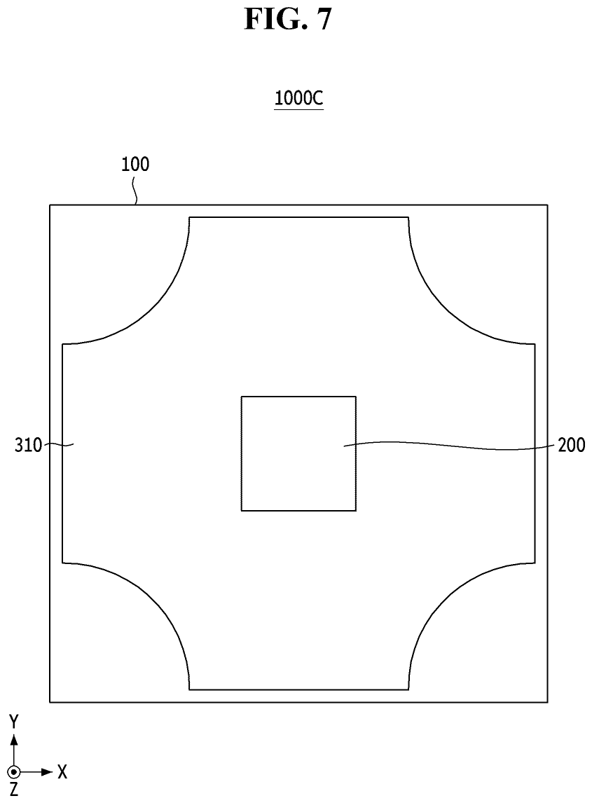

FIGS. 7 to 10 are example schematic diagrams of a semiconductor package according to some embodiments of the present disclosure. For convenience of explanation, differences from the semiconductor packages described with reference to FIGS. 1 to 6 will be mainly described.

Referring to FIG. 7, in a semiconductor package 1000C according to some embodiments, the side face members of the metal structure 310 may include a curved face from the top planar view. For example, the side face members of the metal structure 310 may include, but not limited to, a curved face recessed toward the inside of the substrate 100.

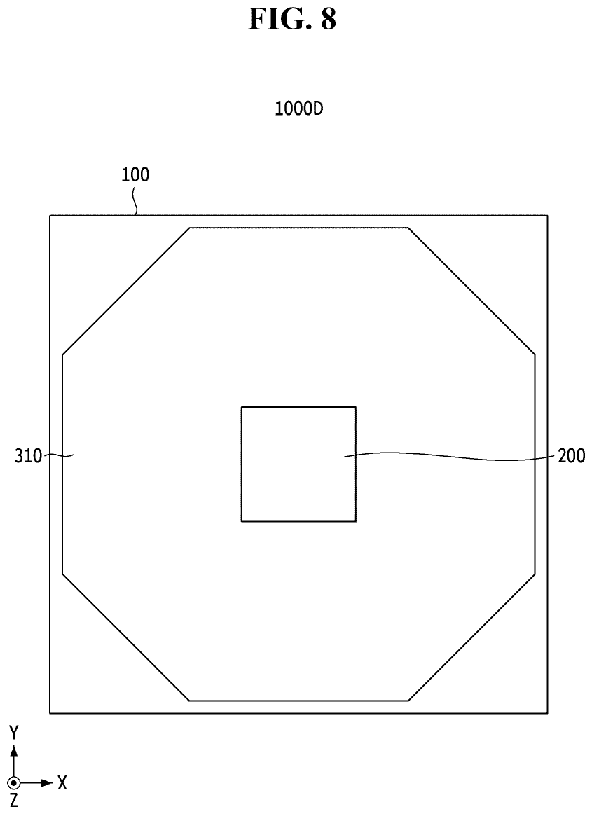

Referring to FIG. 8, in a semiconductor package 1000D according to some embodiments, the metal structure 310 may have a polygonal shape from the top planar viewpoint. For example, the metal structure 310 may have, but not limited to, an octagonal shape from the top planar viewpoint.

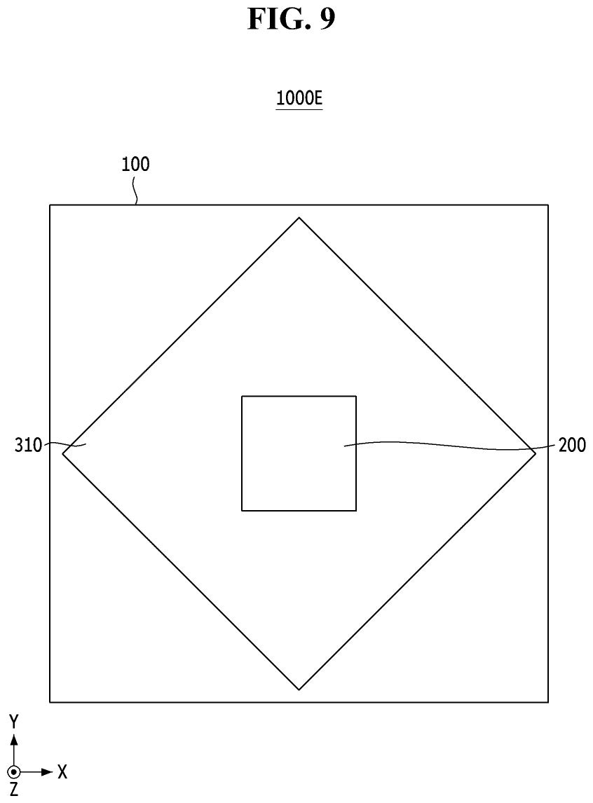

Referring to FIG. 9, in a semiconductor package 1000E according to some embodiments, the metal structure 310 may have a rhombus shape from the top planar viewpoint.

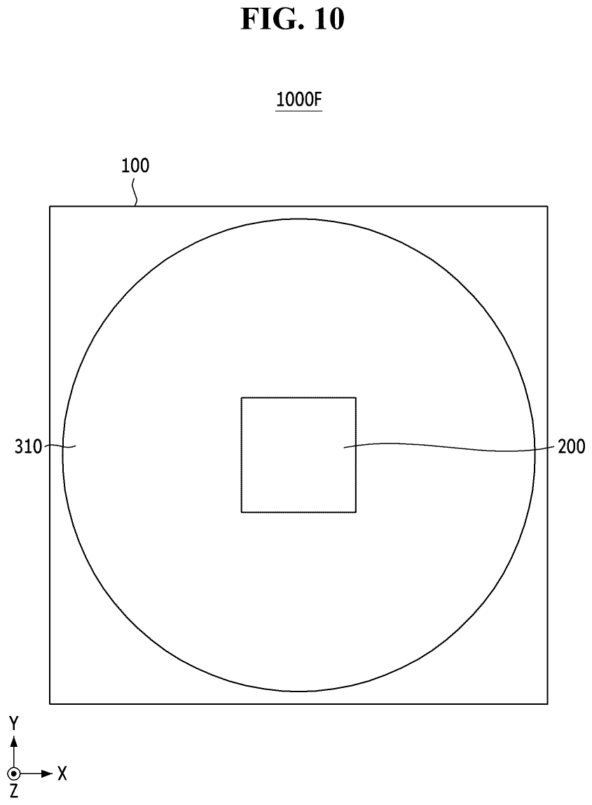

Referring to FIG. 10, in a semiconductor package 1000F according to some embodiments, the metal structure 310 may have a circular shape from the top planar viewpoint.

That is, if the metal structure 310 is not on a plurality of corner regions (CR1 to CR4 of FIG. 1), the shape of the metal structure 310 is not limited to that shown in the drawing.

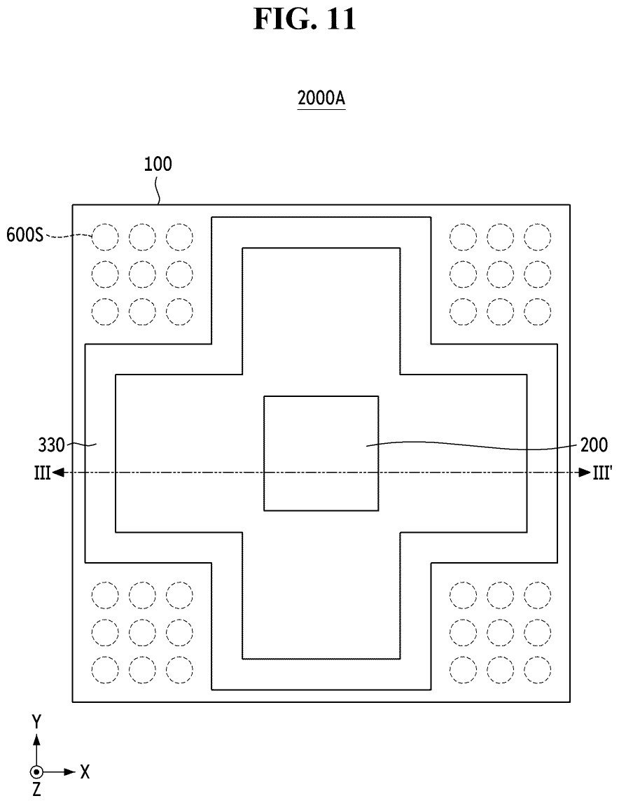

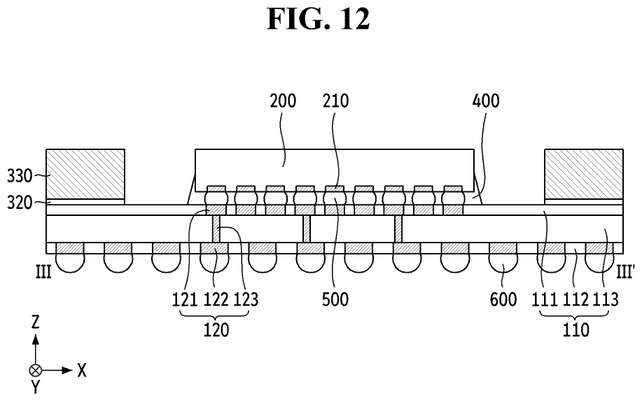

FIG. 11 is an example schematic diagram of a semiconductor package according to some embodiments of the present disclosure. FIG. 12 is a cross-sectional view taken along line III-III′ of FIG. 11. For convenience of explanation, differences from the semiconductor package described using FIGS. 1 to 10 will be mainly explained.

Referring to FIGS. 11 and 12, a metal structure 330 of a semiconductor package 2000A according to some embodiments may be a stiffener.

The metal structure 330 may be around the first semiconductor chip 200. From the top planar viewpoint, the metal structure 330 may surround or be over the side face of the first semiconductor chip 200. The metal structure 330 may not be on the upper face 200_1 of the first semiconductor chip 200. The metal structure 330 may be on the side face of the first semiconductor chip 200.

The metal structure 330 may include at least one metal or metal alloy selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C). When the metal structure 330 is a stiffener, the metal structure 330 may include at least one of copper (Cu), nickel (Ni), and/or stainless steel.

The frame 320 may attach the metal structure 330 onto the first side 100_1 of the substrate 100. The frame 320 may be between the metal structure 330 and the first side 100_1 of the substrate 100.

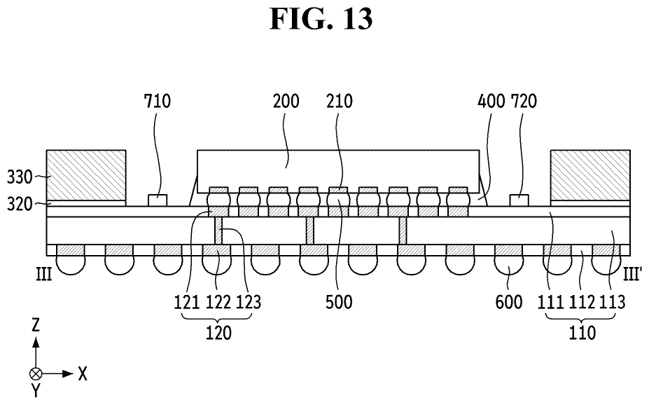

FIG. 13 is a diagram of a semiconductor package according to some embodiments of the present disclosure, and which corresponds to FIG. 12. For convenience of explanation, differences from the semiconductor package explained using FIG. 12 will be mainly explained.

Referring to FIG. 13, the semiconductor package according to some embodiments may further include passive elements 710 and 720.

The passive elements 710 and 720 may be on the first side 100_1 of the substrate 100 to be spaced apart from the first semiconductor chip 200. The passive elements 710 and 720 may be between the first semiconductor chip 200 and the metal structure 330.

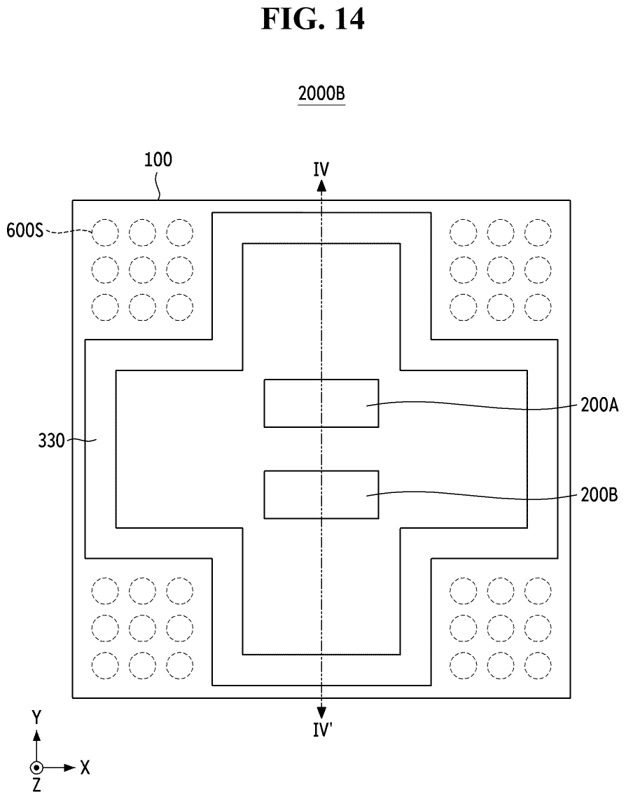

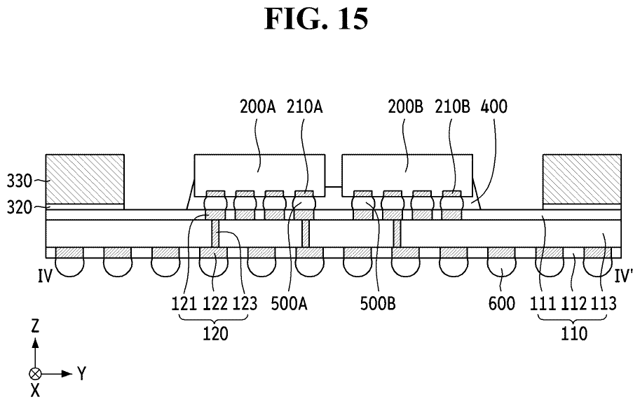

FIG. 14 is an example schematic diagram of a semiconductor package according to some embodiments of the present disclosure. FIG. 15 is a cross-sectional view taken along line IV-IV′ of FIG. 14. For convenience of explanation, differences from the semiconductor package described using FIGS. 1 to 13 will be mainly explained.

Referring to FIGS. 14 and 15, a semiconductor package 2000B according to some embodiments may include first and second semiconductor chips 200A and 200B. The first and second semiconductor chips 200A and 200B may be spaced apart from each other in the first direction Y. The semiconductor package 2000B according to some embodiments may include a plurality of semiconductor chips. The number of semiconductor chips is not limited to those shown in the drawings.

The first semiconductor chip 200A may be on the first side 100_1 of the substrate 100. The first semiconductor chip 200A may be on the first passivation film 111.

The first semiconductor chip 200A may include an application processor (AP) chip such as a micro processor or micro controller, a CPU, a GPU, a modem, an application-specific IC (ASIC), and a logic chip such as a field programmable gate array (FPGA).

The first semiconductor chip 200A may be electrically connected to the substrate 100 through a first connecting bump 500A between the first semiconductor chip 200A and the substrate 100.

The first connecting bump 500A may connect the pad 210A of the first semiconductor chip 200A to the substrate 100. For example, the first connecting bump 500A may be connected to a part of the first wiring 121 of the substrate 100.

The first connecting bump 500A may have, for example, but not limited to, a spherical shape or an elliptical shape. The first connecting bump 500A may include, for example, but not limited to, tin (Sn), indium (In), bismuth (Bi), antimony (Sb), copper (Cu), silver (Ag), zinc (Zn), lead (Pb), and combinations thereof.

The pad 210A of the first semiconductor chip 200A may be on the active face of the first semiconductor chip 200A. The pad 210A may include, for example, but not limited to, copper (Cu), copper alloy, nickel (Ni), palladium (Pd), platinum (Pt), gold (Au), cobalt (Co), and combinations thereof.

The second semiconductor chip 200B may be on the first side 100_1 of the substrate 100. The second semiconductor chip 200B may be on the first passivation film 111.

The second semiconductor chip 200B may include an application processor (AP) chip such as a micro processor or a micro controller, a CPU, a GPU, a modem, an application-specific IC (ASIC), and a logic chip such as a field programmable gate array (FPGA).

The second semiconductor chip 200B may be electrically connected to the substrate 100 through a second connecting bump 500B between the second semiconductor chip 200B and the substrate 100.

The second connecting bump 500B may connect the pad 210B of the second semiconductor chip 200B to the substrate 100. For example, the second connecting bump 500B may be connected to a part of the first wiring 121 of the substrate 100.

The second connecting bump 500B may have, for example, but not limited to, a spherical shape or an elliptical spherical shape. The second connecting bump 500B may include, but not limited to, for example, tin (Sn), indium (In), bismuth (Bi), antimony (Sb), copper (Cu), silver (Ag), zinc (Zn), lead (Pb), and combinations thereof.

The pad 210B of the second semiconductor chip 200B may be on the active face of the second semiconductor chip 200B. The pad 210B may include, but not limited to, for example, copper (Cu), copper alloy, nickel (Ni), palladium (Pd), platinum (Pt), gold (Au), cobalt (Co), and combinations thereof.

The underfill material layer 400 may be formed on the substrate 100. The underfill material layer 400 may be between the first side 100_1 of the substrate 100 and the first and second semiconductor chips 200A and 200B. The underfill material layer 400 may include, but not limited to, an insulating polymer material such as an epoxy molding compound (EMC).

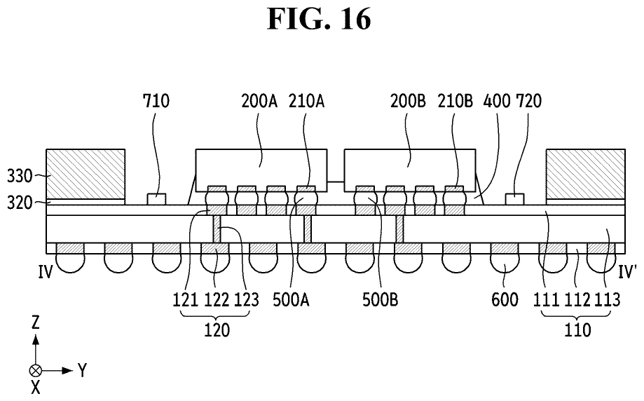

FIG. 16 is a diagram of a semiconductor package according to some embodiments of the present disclosure, and which corresponds to FIG. 15. For convenience of explanation, differences from the semiconductor package described using FIG. 15 will be mainly described.

Referring to FIG. 16, a semiconductor package according to some embodiments may further include passive elements 710 and 720.

The passive elements 710 and 720 may be on the first side 100_1 of the substrate 100 to be spaced apart from the first and second semiconductor chips 200A and 200B. The metal structure 330 may surround or be over the passive elements 710 and 720 from the top planar viewpoint. On the basis of the first direction Y, the passive elements 710 and 720 may be between the metal structure 330 and the first semiconductor chip 200A, and between the metal structure 330 and the second semiconductor chip 200B.

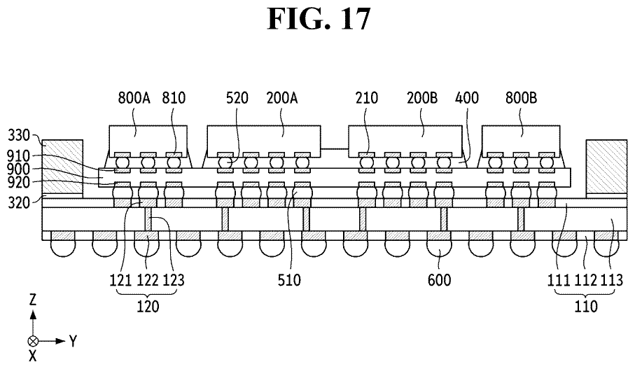

FIG. 17 is a cross-sectional view of a semiconductor package according to some embodiments of the present disclosure. For convenience of explanation, differences from the semiconductor packages described using FIGS. 1 to 16 will be mainly described.

Referring to FIG. 17, the semiconductor package according to some embodiments may further include third and fourth semiconductor chips 800A and 800B and an interposer 900.

The third and fourth semiconductor chips 800A and 800B may be on the interposer 900 to be spaced apart from the first and second semiconductor chips 200A and 200B in the first direction Y.

The third and fourth semiconductor chips 800A and 800B may be connected to the interposer 900 through a pad 810 and an upper connecting bump 520 on the lower faces of each of the third and fourth semiconductor chips 800A and 800B.

On the basis of the third direction Z, the interposer 900 may be between the substrate 100 and the first and second semiconductor chips 200A and 200B. The interposer 900 may be between the substrate 100 and the third and fourth semiconductor chips 800A and 800B.

The interposer 900 may include an upper pad 910 and a lower pad 920. The upper pad 910 may be connected to the upper connecting bump 520. The lower pad 920 may be connected to the lower connecting bump 510.

The substrate 100 may be electrically connected to the first and second semiconductor chips 200A and 200B through the upper pads 910 and the lower pads 920. The substrate 100 may be electrically connected to the third and fourth semiconductor chips 800A and 800B through the upper pad 910 and the lower pad 920.

The first and second semiconductor chips 200A and 200B and the third and fourth semiconductor chips 800A and 800B may be mounted on the substrate 100 by a flip chip bonding way.

Each of the first and second semiconductor chips 200A and 200B may include an application processor (AP) chip such as a micro processor or a micro controller, a CPU, a GPU, a modem, an application-specific IC (ASIC), and a logic chip such as a field programmable gate array (FPGA).

Although it is not specifically shown, each of the third and fourth semiconductor chips 800A and 800B may include a semiconductor chip stack structure. For example, the semiconductor chip stack structure may include a dynamic random access memory (DRAM), a static random access memory (SRAM), a flash memory, an electrically erasable programmable read-only memory (EEPROM), a phase-change random access memory (PRAM), a magnetic random access memory (MRAM) or a resistive random access memory (RAM).

When the semiconductor chip stack structure includes a memory semiconductor chip having an HBM DRAM cell, the semiconductor chip stack structure may further include a buffer chip for controlling the HBM DRAM.

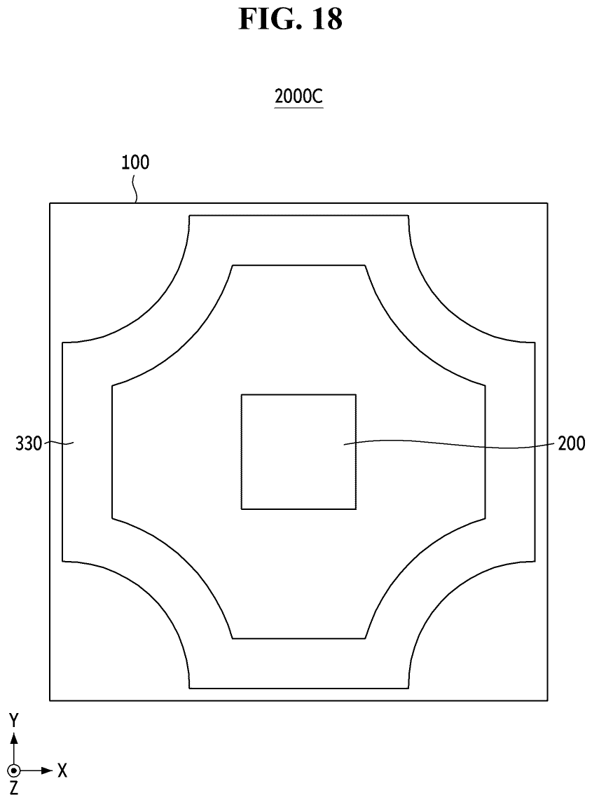

FIGS. 18 to 21 are example schematic diagrams of the semiconductor package according to some embodiments of the present disclosure. For convenience of explanation, differences from the semiconductor package described using FIGS. 1 to 17 will be mainly explained.

Referring to FIG. 18, in a semiconductor package 2000C according to some embodiments, the side face members of the metal structure 330 may include a curved face from the top planar viewpoint. For example, the side face members of the metal structure 330 may include, but not limited to, a curved face recessed toward the inside of the substrate 100.

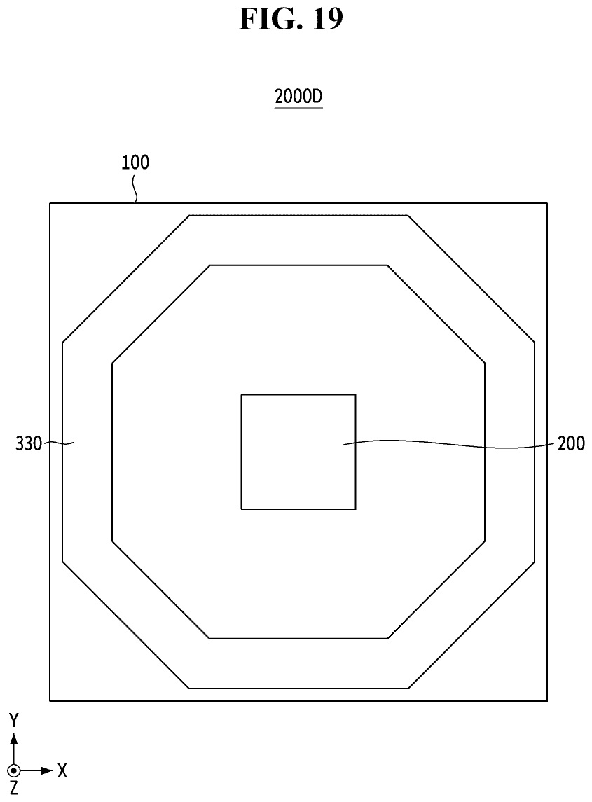

Referring to FIG. 19, in a semiconductor package 2000D according to some embodiments, the metal structure 330 may have a polygonal shape from the top planar viewpoint. For example, the metal structure 330 may have, but not limited to, an octagonal shape from the top planar viewpoint.

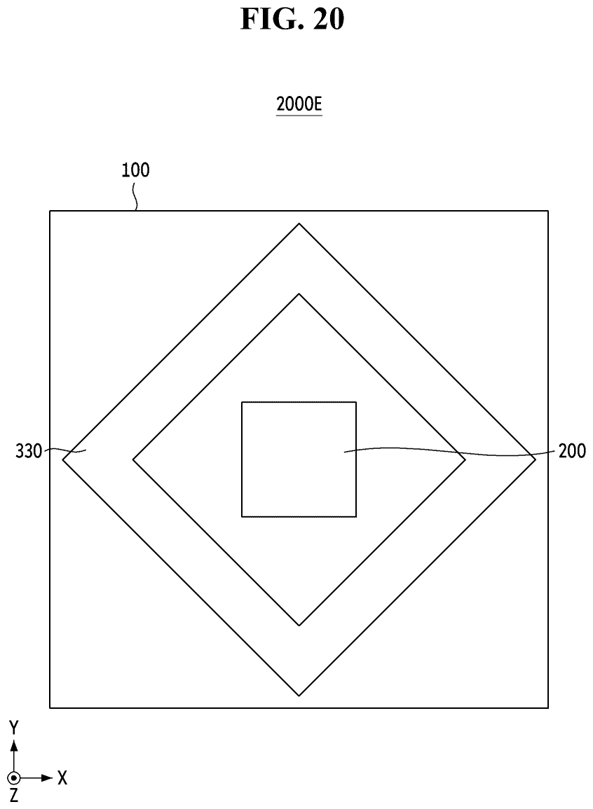

Referring to FIG. 20, in a semiconductor package 2000E according to some embodiments, the metal structure 330 may have a rhombus shape from the top planar viewpoint.

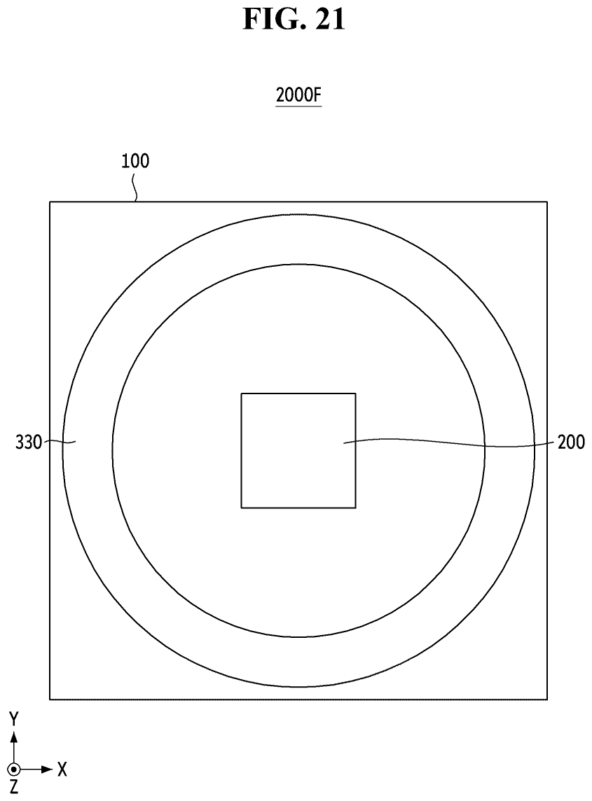

Referring to FIG. 21, in a semiconductor package 2000F according to some embodiments, the metal structure 330 may have a circular shape from the top planar viewpoint.

That is, if the metal structure 330 is not on a plurality of corner regions (CR1 to CR4 of FIG. 1), the shape of the metal structure 330 is not limited to that shown in the drawings.

According to some embodiments of the present disclosure, a heat slug or a stiffener including a metal material may not be in the corner regions (CR1 to CR4 of FIG. 1) of the substrate 100. Accordingly, it is possible to reduce warpage that occurs depending on the difference in the thermal expansion coefficient of the individual components that make up the semiconductor package.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor package comprising:
a substrate comprising an inner region extending in a first direction and a second direction that intersects the first direction, a plurality of corner regions around the inner region, first and third side faces opposite to each other in the first direction, second and fourth side faces opposite to each other in the second direction, and first and second sides that connect the first and third side faces and are opposite to each other in a third direction perpendicular to the first and second directions;
a first semiconductor chip on the substrate;
a metal structure on the first semiconductor chip and extending over sides of the first semiconductor chip; and
a connecting structure on the second side of the substrate, and electrically connected to the first semiconductor chip, p1 wherein the metal structure is inside the first to fourth side faces of the substrate, and in a region that excludes the plurality of corner regions among regions on the first side of the substrate.

2. The semiconductor package of claim 1, p1 wherein the metal structure includes:
a first side face first member spaced apart from the first side face of the substrate in a direction parallel to the first direction, and a first side face second member spaced apart from the fourth side face of the substrate in a direction parallel to the second direction, p1 a second side face first member spaced apart from the first side face of the substrate in the direction parallel to the first direction, and a second side face second member spaced apart from the second side face of the substrate in the direction parallel to the second direction, p1 a third side face first member spaced apart from the third side face of the substrate in the direction parallel to the first direction, and a third side face second member spaced apart from the second side face of the substrate in the direction parallel to the second direction, and p1 a fourth side face first member spaced apart from the third side face of the substrate in the direction parallel to the first direction, and a fourth side face second member spaced apart from the fourth side face of the substrate in the direction parallel to the second direction.

3. The semiconductor package of claim 1, p1 wherein the metal structure is spaced apart by a first distance from each of the first and third side faces of the substrate in a direction parallel to the first direction, and p1 the metal structure is spaced apart by a second distance from the second and fourth side faces of the substrate in the direction parallel to the second direction.

4. The semiconductor package of claim 3, p1 wherein each of the first distance and the second distance is 2 mm to 3 mm.

5. The semiconductor package of claim 1, p1 wherein the metal structure is not in each of the plurality of corner regions, and is in the inner region.

6. The semiconductor package of claim 2, p1 wherein the first side face first member, the second side face second member, the second side face first member, the second side face second member, the third side face first member, the third side face second member, the fourth side face first member, and the fourth side face second member of the metal structure includes a curved shape from a top planar viewpoint.

7. The semiconductor package of claim 1, p1 wherein the metal structure has a cross (+) shape from a top planar viewpoint.

8. The semiconductor package of claim 1, p1 wherein the metal structure has a polygonal shape from a top planar viewpoint.

9. The semiconductor package of claim 1, p1 wherein the metal structure includes at least one of Cu, Ni, and stainless steel.

10. A semiconductor package comprising:
a substrate comprising an inner region extending in a first direction and a second direction that intersects the first direction, a plurality of corner regions around the inner region, and first and second sides that are opposite to each other in a third direction perpendicular to the first direction and the second direction;
a first semiconductor chip on the first side of the substrate;
a metal structure which on the first side of the substrate, and on and extending over sides of the first semiconductor chip; and
a connecting structure on the second side of the substrate, and electrically connected to the first semiconductor chip, p1 wherein the metal structure is not in the plurality of corner regions and is in the inner region.

11. The semiconductor package of claim 10, p1 wherein the metal structure exposes the first side of the substrate in each of the plurality of corner regions from a top planar view point.

12. The semiconductor package of claim 10, p1 wherein the first semiconductor chip includes a lower face opposite to the first side of the substrate, and an upper face opposite the lower face, and p1 the metal structure is on the upper face of the first semiconductor chip.

13. The semiconductor package of claim 10, further comprising:
a passive element spaced apart from the first semiconductor chip on the first side of the substrate.

14. The semiconductor package of claim 10, further comprising:
a second semiconductor chip spaced apart from the first semiconductor chip on the first side of the substrate.

15. The semiconductor package of claim 14, further comprising:
an interposer between the substrate and the first and second semiconductor chips; and
a third semiconductor chip spaced apart from the first and second semiconductor chips on the interposer.

16. A semiconductor package comprising:
a substrate comprising an inner region extending in a first direction and a second direction that intersects the first direction, a plurality of corner regions around the inner region, first and third side faces opposite to each other in the first direction, and second and fourth side faces opposite to each other in the second direction;
a first semiconductor chip on an upper side of the substrate;
a metal structure on the first semiconductor chip, and in a region that excludes the plurality of corner regions on the upper side of the substrate;
an underfill material layer between the upper side of the substrate and the first semiconductor chip;
a connecting bump that connects a pad of the first semiconductor chip to the substrate; and
connecting structures on a lower side of the substrate, p1 wherein the metal structure includes a plurality of first side face members adjacent the corner regions in a direction parallel to the first direction, and a plurality of second side face members adjacent the connecting structures in a direction parallel to the second direction.

17. The semiconductor package of claim 16, p1 wherein the metal structure is on an inner region of the substrate and around the side faces of the first semiconductor chip, from a planar viewpoint.

18. The semiconductor package of claim 16, p1 wherein the metal structure is not on the upper side of the substrate in each of the plurality of corner regions.

19. The semiconductor package of claim 16, further comprising:
a second semiconductor chip spaced apart from the first semiconductor chip in the first direction, on the upper side of the substrate.

20. The semiconductor package of claim 16, p1 wherein the connecting structures are electrically connected to the first semiconductor chip.
